(19) United States
(12) Patent Application Publication
(10) Pub. No.: US 2012/0273244 A1
(43) Pub. Date: Nov. 1, 2012

(54) ELECTRONIC DEVICE

(75) Inventors: Hiroyuki TAKITA, Kawasaki (JP); Yoshifumi KAJIWARA, Kawasaki (JP); Takashi SUZUKI, Kawasaki (JP); Kazuhiro TADA, Kawasaki (JP); Hiroshi KUBO, Kawasaki (JP)

(73) Assignee: FUJITSU LIMITED, Kawasaki-shi (JP)

(21) Appl. No.: 13/426,384

(22) Filed: Mar. 21, 2012

(30) Foreign Application Priority Data
Mar. 31, 2011 (JP) 2011-077399

(51) Int. Cl. H05K 5/00

(52) U.S. Cl. 174/50

(57) ABSTRACT

An electronic device including: a housing that has a cable insertion hole; a gel member that covers the cable insertion hole to shut water off, a cable being inserted through the cable insertion hole; a holding member, formed in synthetic resin, that has a first protruding portion to pass through the gel member, the first protruding portion projecting into the cable insertion hole, the holding member mounting and holding the gel member to the housing; and a fixing unit that fixes the holding member to the housing by passing through the gel member.

### CROSS REFERENCE TO RELATED APPLICATION

This application is based upon and claims the benefit of priority from the prior Japanese Patent Application NO. 2011-077399 filed on Mar. 31, 2011, the entire contents of which are incorporated herein by reference.

### FIELD

The embodiments disclosed hereafter is related to an electronic device having a water shut-off structure for a housing into which a cable is inserted.

### BACKGROUND

Some of portable electronic devices such as cellular phones have a water shut-off structure, for example, as a waterproof function for the interior of a housing thereof at a joint portion of housing cases constituting the housing or the like.

There are known portable electronic devices that comprise a plurality of housings foldably or anteroposteriorly-slidabley connected so that one of the housings may move against the other, for example. In such a portable electronic device, a cable member such as a flexible cable, for example, is provided for mutually connecting circuit boards mounted in a stationary housing and a movable housing. These housings have an opening on a housing case thereof through which the cable member is inserted into the interior thereof. In order to maintain a waterproof function of the portable electronic device, the opening also needs to provide a water shut-off structure.

As an electronic device having a water shut-off structure for such an opening through which a cable passes, there is a known electronic device in which a housing case of a stationary housing and a housing case of a movable housing are rotatably connected at a hinge and circuit boards provided in each of the housings are connected by a flexible cable through a water shut-off structure. The water shut-off structure includes a water shut-off gel, which is provided at a joint portion of a first housing case and made by forming gelled material into a shape of a rectangular solid, and a press member, which is provided at a joint portion of a second housing case corresponding to the first housing case and made of material such as a TPEE (thermoplastic polyester elastomer). The flexible cable is held between the water shut-off gel and the press member. When the first housing case and the second housing case are joined, the press member presses the flexible cable and the water shut-off gel and the water shut-off gel is deformed.

### [Patent Document]

Japanese Laid-Open Patent Publication No. 2009-26966

With a water shut-off structure using a gelled member, the periphery of a flexible cable is sealed by the gelled member being compressed and deformed. But depending on an installation place of the gelled member, some portion of the gelled member may be pressed directly by a pressing member while the other portion may be pressed via the flexible cable, and this causes different compressing ratios at different portions on the gelled member according to specific pressing conditions. Thus, the periphery of the flexible cable may not be sealed completely.

If a large number of pressing members are to be used to increase the compressing ratio of the gelled member at the periphery of the flex cable, for example, more space will be needed for installing those pressing members, preventing the downsizing of an electric device such as a cellular phone.

### SUMMARY

According to an aspect of the embodiments, there is an electronic device includes: a housing that has a cable insertion hole; a gel member that covers the cable insertion hole to shut water off, a cable being inserted through the cable insertion hole; a holding member, formed in synthetic resin, that has a first protruding portion to pass through the gel member, the first protruding portion projecting into the cable insertion hole, the holding member mounting and holding the gel member to the housing; and a fixing unit that fixes the holding member to the housing by passing through the gel member.

The object and advantages of the embodiments will be realized and attained by means of the elements and combinations particularly pointed out in the claims.

It is to be understood that both the foregoing general description and the following detailed description are exemplary and explanatory and are not restrictive of the embodiments, as claimed.

### BRIEF DESCRIPTION OF THE DRAWINGS

FIG. 1 is a diagram depicting a configuration example of a cellular phone in accordance with a first embodiment;

FIG. 2 is a diagram depicting an external configuration example of the cellular phone in a closed state;

FIG. 3 is a diagram depicting an external configuration example of the cellular phone in an open state;

FIG. 4 is a diagram depicting an example of a state of cable insertion and disposing and configuring a water shut-off component in a first housing;

FIG. 5 is a diagram depicting an example of a state in which the water shut-off component is disposed at an insertion hole;

FIG. 6 is a diagram depicting a configuration example of the water shut-off component at a surface thereof which contacts with the cable;

FIG. 7 is a diagram depicting an example of a state in which a gel member and a base member are separated;

FIG. 8 is a diagram depicting an external configuration example of the base member;

FIG. 9 is a cross-sectional view as taken along line IX-IX of FIG. 5;

FIG. 10 is a cross-sectional view as taken along line X-X of FIG. 2;

FIG. 11 is a diagram depicting an example of disposing a water shut-off component on a stationary housing unit of a second embodiment;

FIG. 12 is a diagram depicting an example of a state of the water shut-off component caused by opening and closing a cellular phone;

FIG. 13 is a diagram depicting an example of the water shut-off structure in a stationary housing unit of a third embodiment;

FIG. 14 is a diagram depicting a configuration example of the water shut-off component in the stationary housing unit;

FIG. 15 is a diagram depicting a configuration example of the water shut-off component at a side thereof which contacts with a cable;

FIG. 16 is a diagram depicting a configuration example of the water shut-off component;

FIG. 17 is an example of a cross-sectional view taking along line A-A of FIG. 13;

FIG. 18 is an example of a cross-sectional view taking along line B-B of FIG. 13; and

FIG. 19 is a diagram depicting an external configuration example of a PC in accordance with another embodiment.

### DESCRIPTION OF THE EMBODIMENTS

### First Embodiment

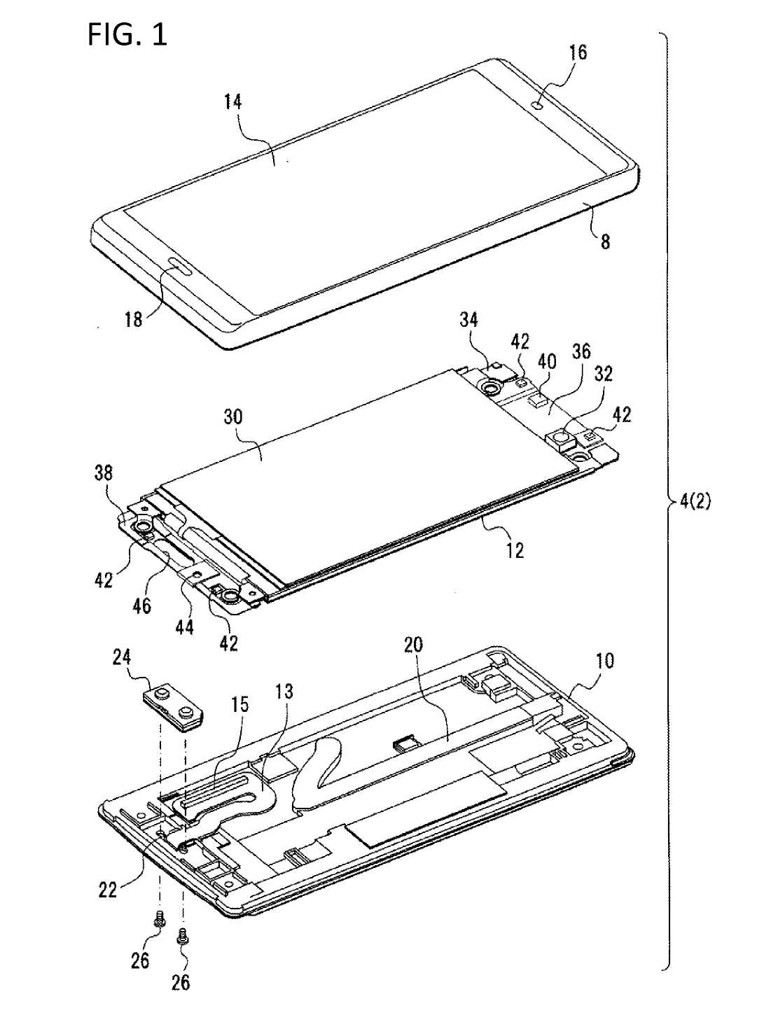

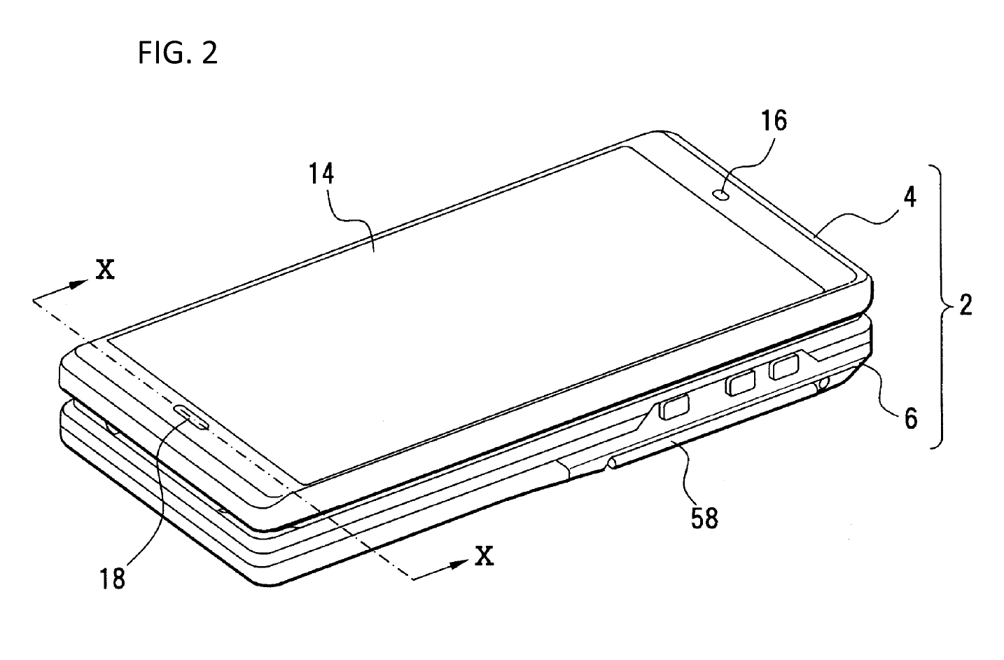

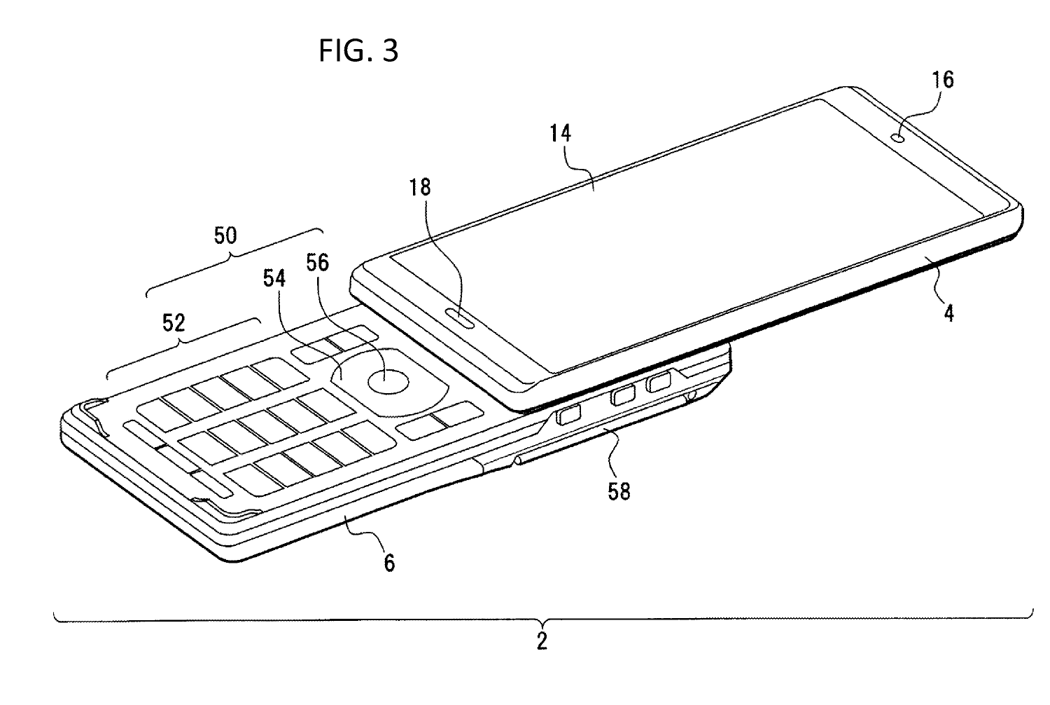

With respect to a first embodiment, FIGS. 1, 2 and 3 will now be referenced. FIG. 1 is a diagram depicting a configuration example of a cellular phone in accordance with a first embodiment; FIG. 2 is a diagram depicting an external configuration example of the cellular phone in a closed state; and FIG. 3 is a diagram depicting an external configuration example of the cellular phone in an open state. Configurations depicted in FIGS. 1 to 3 are an example and the present embodiment is not limited to these.

A cellular phone 2 is an example of an electronic device of the present disclosure. As depicted in FIG. 3, the cellular phone 2 includes, for example, a first housing unit 4 and a second housing unit 6 (see FIG. 2) stacked so as to be slidable in a longitudinal direction. The housing unit 4 mainly constitutes a display-side housing unit, for example, and the housing unit 6 mainly constitutes an operation-side housing unit.

The housing unit 4 is an example of a housing of the electronic device of the present disclosure, and constitutes a movable housing unit capable of sliding against the housing unit 6, for example. The housing unit 4 depicted in FIG. 1 includes, for example, a movable front case 8 and a movable rear case 10 between which a circuit board unit 12 is provided. The movable front case 8 and the movable rear case 10 are molded bodies made of resin material, for example. The housing unit 4 is electrically connected to the housing unit 6 by a cable 13

On the movable front case 8, a display window portion 14 is created to which a liquid crystal display panel 30 of the circuit board unit 12 fits to achieve display. The display window portion 14 may include a touch panel module, for example, as operational input means. At front and rear ends in a longitudinal direction of the movable front case 8, a sound emission hole 16 and a sound absorption hole 18 are provided, respectively, for using in a verbal communication function or the like, for example.

On an interior side surface of the movable front case 8, an anchoring nail for anchoring to the movable rear case 10 or the circuit board unit 12 is formed, for example, and a waterproof member may be disposed to prevent ingress of water or the like into the interior of the housing unit 4.

On the movable rear case 10, the circuit board unit 12 is mounted and held, and the cable 13 inserted into the interior of the housing unit 4 is disposed according to the mounting position of the circuit board unit 12. The cable 13 has a connecter 15 at one end thereof, for example, and the connector 15 is connected to a not-shown connector disposed on the circuit board unit 12.

Formed on the movable rear case 10 are a slide guide 20, which enables the housing unit 4 to slide against the housing unit 6, and an insertion hole 22, through which the cable 13 is inserted into the interior of the housing unit 4. Also on the movable rear case 10, a water shut-off component 24 for preventing ingress of water or the like from the insertion hole 22 is disposed. The water shut-off component 24 covers the insertion hole 22 through which the cable 13 is inserted, and is fixed from a back surface of the movable rear case 10 by screws 26, for example.

The screws 26 are not only fixing means for fixing the water shut-off component 24 to the movable rear case 10 but also an example of biasing means for pressing the water shut-off component 24 to the movable rear case 10. Means for fixing the water shut-off component 24 is not limited to the screws 26, and a fixing component utilizing a fastening part, an anchoring part, or the like is used.

The circuit board unit 12 is an example of a functional configuration unit placed in the movable housing unit 4, and one or more functional components are mounted thereon. Mounted on the circuit board unit 12 are: the liquid crystal display panel 30; a camera 32; an antenna function component 34; flexible circuit boards 36 and 38 at both front and rear ends in a longitudinal direction of the liquid crystal display panel 30; and the like. On the flexible circuit board 36, a speaker 40, an LED (Light Emitting Diode) element 42, etc. are mounted.

On the flexible circuit board 38, the LED element 42, a microphone component 44, an antenna function, etc. are mounted. On the flexible circuit board 38, an opening 46 is formed, for example, to avoid contacting with the water shut-off component 24 when placed on the movable rear case 10.

As depicted in FIG. 2, in the cellular phone 2, the housing unit 4 is stacked on the housing unit 6, and in a closed state an upper surface of the housing unit 6 is covered with the housing unit 4 to prevent touch operation. With the cellular phone 2, it is possible, for example, to use a verbal communication function and a display function for displaying web sites, e-mails, etc. even in the closed state. Also, a touch panel disposed on the display window portion 14 may be used for manipulating the cellular phone 2.

As depicted in FIG. 3, when the housing unit 4 slides in a longitudinal direction, for example, the upper surface of the housing unit 6 becomes exposed. The housing unit 6 is an example of the operation-side housing unit of the cellular phone 2, and constitutes a stationary housing unit with respect to the housing unit 4 which is slidable. The housing unit 6 provides a key pad 50 which includes ten keys 52, an enter key 56, a cursor key 54, and the like. The housing unit 6 also provides an antenna 58 for sending and receiving TV or data signals, for example, at a front end portion on a side surface thereof.

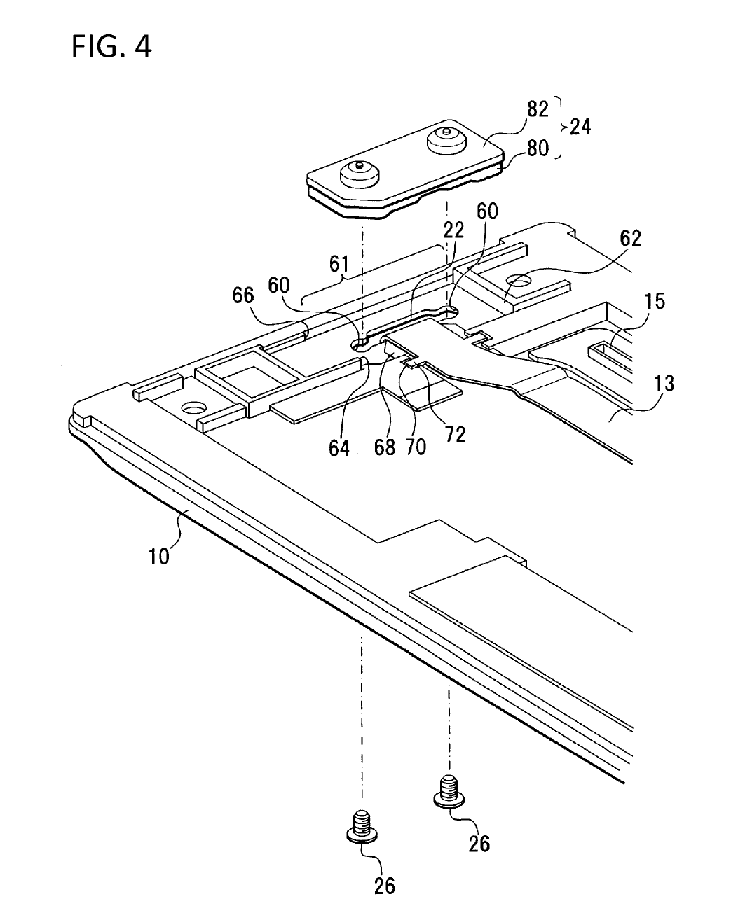

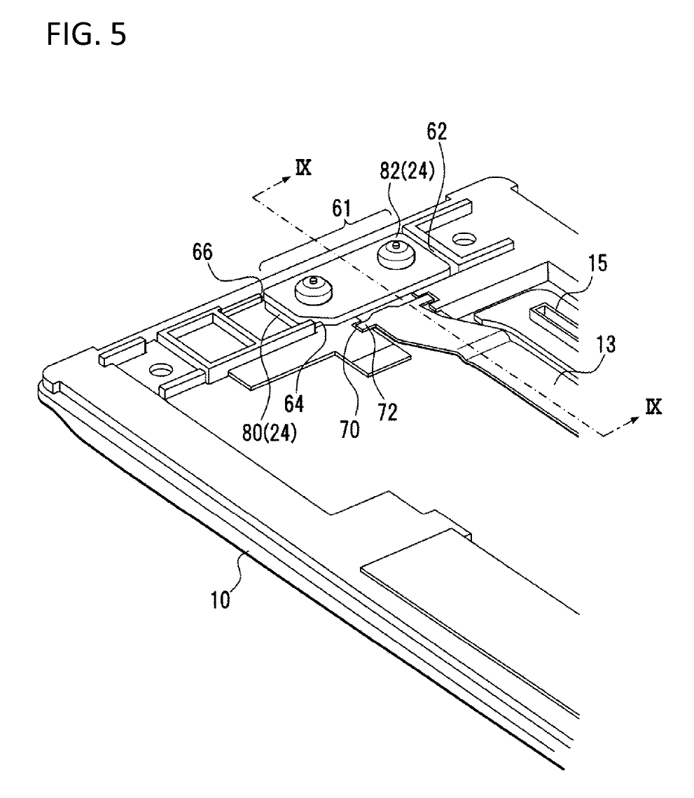

With respect to the configuration of a water shut-off function disposed at the interior of the first housing unit, FIGS. 4 and 5 will now be referenced. FIG. 4 is a diagram depicting an example of a state of cable insertion and disposing and configuring a water shut-off component in a first housing; and FIG. 5 is a diagram depicting an example of a state in which the water shut-off component is disposed at an insertion hole. Configurations depicted in FIGS. 4 to 5 are an example and the present embodiment is not limited to these.

The insertion hole 22 of the movable rear case 10 is larger than the cross-sectional area of the cable 13, and has fixing holes 60 at both ends in a longitudinal direction for inserting the screws 26 to fix the water shut-off component 24. Even though the fixing holes 60 depicted in FIG. 4 are formed so as to be integrated with the insertion hole 22, they are not limited to this and may be formed separately from the insertion hole 22.

On the movable rear case 10, guide walls 62, 64 and 66 for guiding the water shut-off component 24 are formed, for example, at the periphery of the insertion hole 22 to constitute a water shut-off area 61 and define an installation location for the water shut-off component 24. The guide walls 62, 64 and 64 partly or entirely contact with each of the side surfaces of the water shut-off component 24. It is not requested that all of the guide walls 62, 64 and 66 contact with the water shut-off component 24, as long as they are close enough to the water shut-off component 24 to guide into a specific position on the movable rear case 10.

Also on the movable rear case 10, an adhesive member 68 is disposed at a portion of the periphery of the insertion hole 22, for example, for fixing the cable 13. A part of the adhesive member 68 is placed within the water shut-off area 61, for example, and the water shut-off component 24 is then disposed along with the cable 13. Also formed on the movable rear case 10 is an anchoring concave portion 70, for example, for anchoring the cable 13. At a part of the cable 13, an anchoring convex portion 72 is formed, for example, for anchoring at the anchoring concave portion 70.

The water shut-off component includes: a gel member 80 which contacts with the cable 13; and a base member 82, for example. The gel member 80 shuts water off by covering the insertion hole 22 through which the cable 13 is inserted. The base member 82 is formed in synthetic resin, for example, and is an example of a holding member for disposing and holding the gel member 80 on the movable rear case 10.

When the water shut-off component 24, depicted in FIG. 5, is placed within the water shut-off area 61 in accordance with the guide walls 62, 64 and 66 and fixed by the screws 26 from a back surface of the movable rear case 10, the gel member 80 adheres into the water shut-off area 61 and seals the periphery of the cable 13.

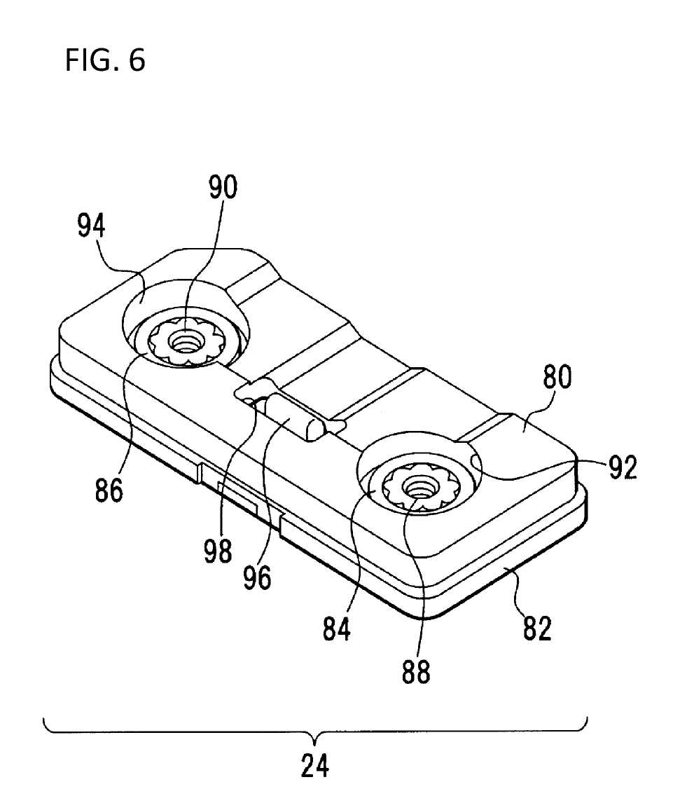

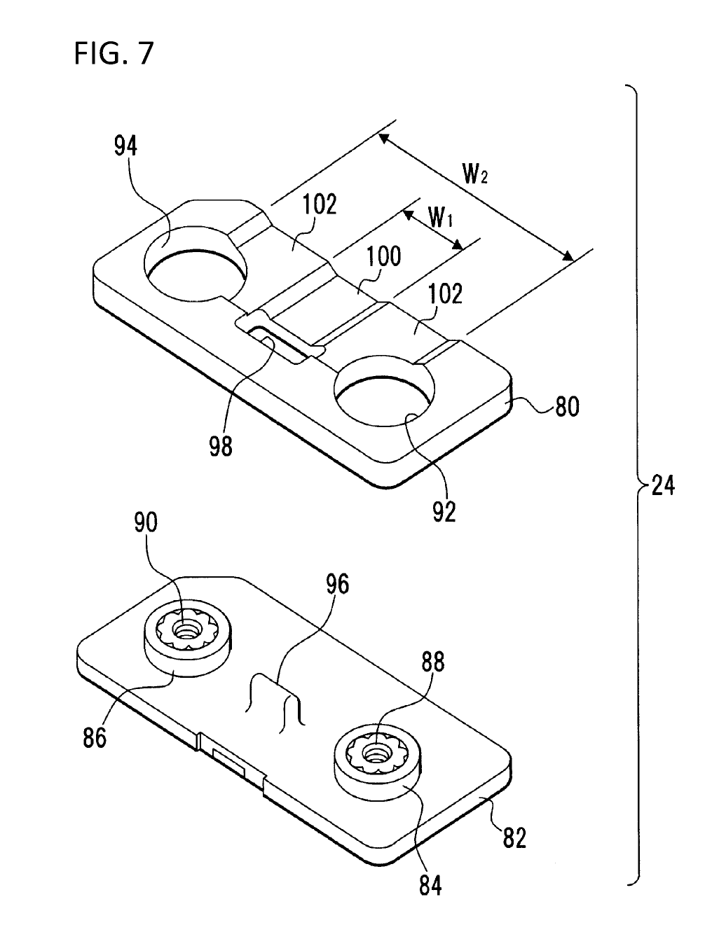

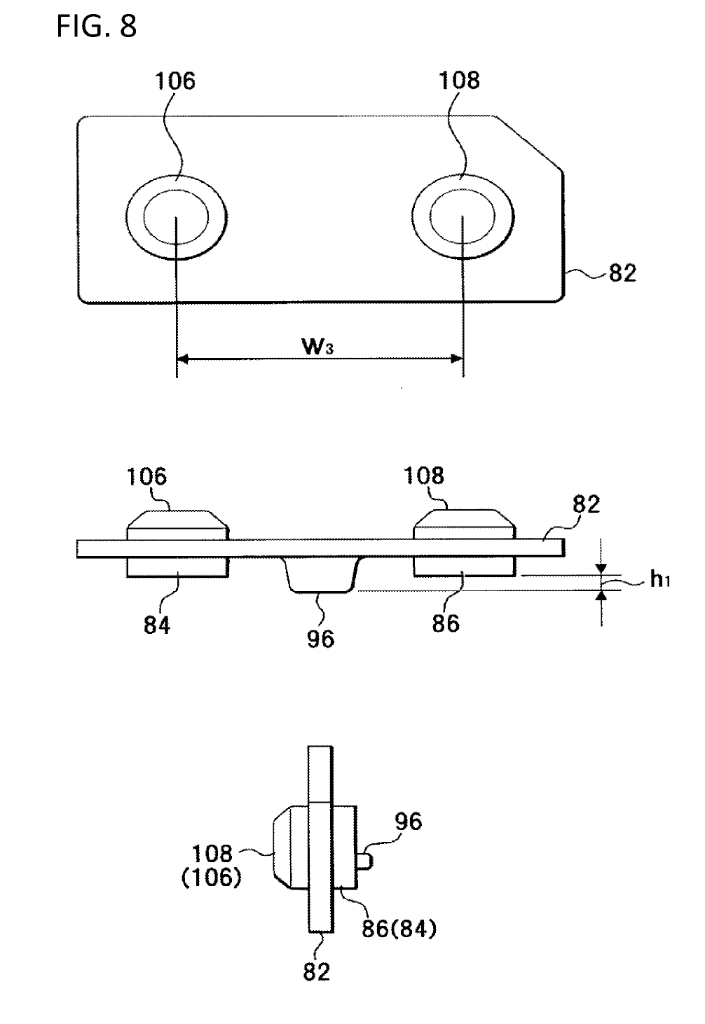

With respect to the configuration of the water shut-off component, FIGS. 6, 7 and 8 will now be referenced. FIG. 6 is a diagram depicting a configuration example of the water shut-off component at a surface thereof which contacts with the cable; FIG. 7 is a diagram depicting an example of a state in which the gel member and the base member are separated; and FIG. 8 is a diagram depicting an external configuration example of the base member. Configurations depicted in FIGS. 6 to 8 are an example and the present embodiment is not limited to these.

The water shut-off component 24 is configured by integrating the gel member 80 and the base member 82, with one side of the gel member 80 and one side of the base member 82 contacting with each other under a pressing force or by an adhesive agent, for example. The gel member 80 is made of material that has high viscosity, no liquidity, and no permeability to water or the like, and deforms under a pressure or the like. At a central portion on a surface of the base member 82, which contacts with the gel member 80, two circular projecting portions 84 and 86 are formed at a predetermined distance. The projecting portions 84 and 86 project toward the gel member 80, and into the interior thereof screw portions 88 and 90 are inserted to which the screws 26 are tightened.

On the gel member 80, through holes 92 and 94 are formed so that the projecting portions 84 and 86 are positioned at the interior thereof and the screws 26 may pass through the gel member 80. The through holes 92 and 94 are an example of a firs t through hole of the present disclosure.

On the base member 82, a projecting portion 96 is formed between the projecting portions 84 and 86, for example, to pass through the gel member 80. On the gel member 80, a thorough hole 98 is formed through which the projecting portion 96 passes. The thorough hole 98 is an example of a second through hole of the present disclosure.

As depicted in FIG. 7, on a surface of the gel member 80 which contacts with the cable 13, two levels of steps are formed, for example, to constitute concave portions 100 and 102. A width W₁ in a longitudinal direction of the concave portion 100, which is deeper than the concave portion 102, is narrower than the width of the cable 13. When disposed on the movable rear case 10, the concave portion 100 is positioned at a substantial center in a width direction of the cable 13. The concave portion 100 is formed so as to be integrated with the through hole 98.

The concave portion 102 is formed at both sides of the concave portion 100 in a longitudinal direction of the gel member 80 and has a border with the through holes 92, 94 and 98. The concave portion 102 is a portion which contacts with the cable 13 when the gel member 80 is disposed on the movable rear case 10. A width W₂ in a longitudinal direction of the concave portion 102 is wider than the width of the cable 13.

The depth of the concave portion 100 and the concave portion 102 may be determined in consideration of the thickness of the cable 13, the thickness of the adhesive member 68 to attach the cable 13 to the movable rear case 10, and the like.

By projecting into the thorough holes 92 and 94 of the gel member 80, the projecting portions 84 and 86 of the base member 82 hold the gel member 80 to maintain the unity of the base member 82 and the gel member 80, and prevent the gel member 80 from sliding out of the base member 82, for example. The screw portions 88 and 90 formed in the projecting portions 84 and 86 are disposed in an insert molding method when the base member 82, which is made of resin, is molded, for example.

The screw portions 88 and 90 are not limited to a separate part disposed in an insert molding method. For example, the interior of the projecting portions 84 and 86 of the base member 82 may be molded into a screw hole.

As depicted in FIG. 8, the projecting portion 96 is formed at a central portion on the base member 82 so as to be higher than the projecting portions 84 and 86 for a high h₁, for example, and projects from the thorough hole 98 of the gel member 80, as described above. The projecting portion 96 is formed according to the position of the insertion hole 22 of the movable rear case 10 and projects into the insertion hole 22.

On a surface of the base member 82 opposite to the surface which contacts with the gel member 80, projecting portions 106 and 108 are formed. The projecting portions 106 and 108 are integrally molded with the base member 82 in resin, and have hollows at the interior thereof which are connected with the projecting portions 84 and 86. The projecting portions 106 and 108 constitute housing portions for housing the screws 26 inserted from the side of the projecting portions 84 and 86. A mounting distance of the screws 26 is set to a width W₃, for example. Since the projecting portions 106 and 108 prevent the screws 26, which are made of metal, from exposing into the interior of the housing unit 4 (see FIG. 1), they work as insulators against electronic components disposed at the periphery of the water shut-off component 24. The width W₃ may be set to be equal to the width W₂ in a longitudinal direction of the concave portion 102 formed on the gel member 80, for example.

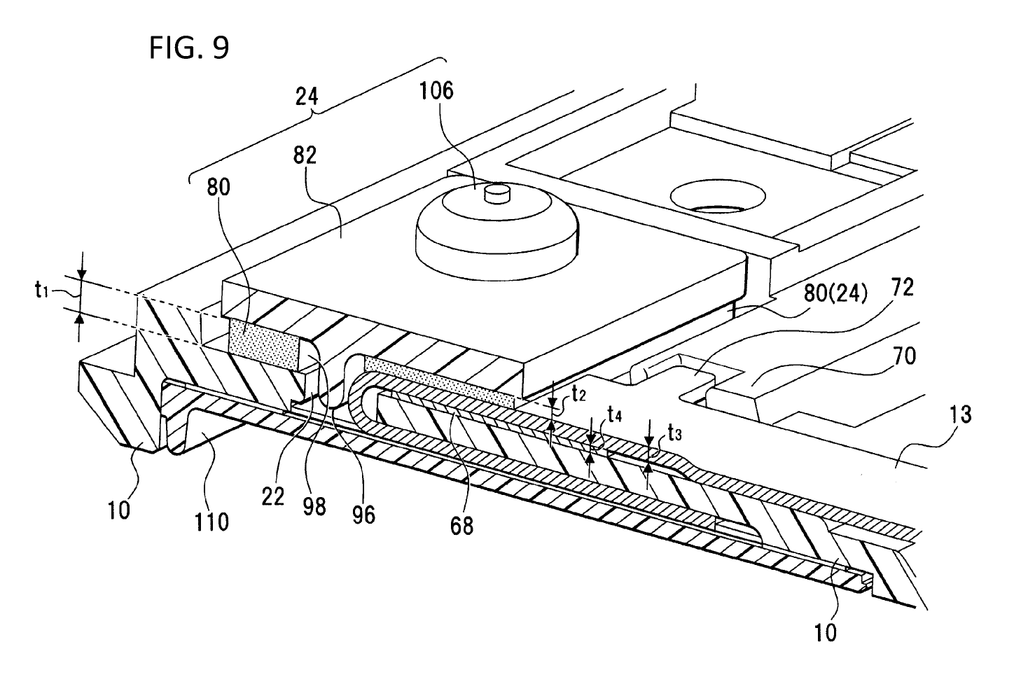

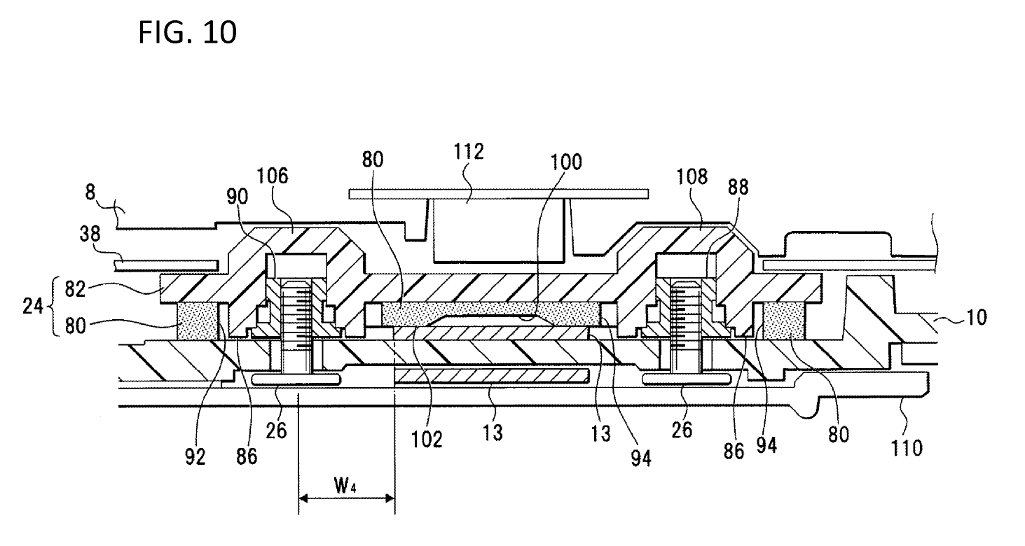

With respect to a state of cable insertion, FIGS. 9 and 10 will be now referenced. FIG. 9 is a cross-sectional view as taken along line IX-IX of FIG. 5; and FIG. 10 is a cross-sectional view as taken along line X-X of FIG. 2. Configurations depicted in FIGS. 9 and 10 are an example and the present embodiment is not limited to these.

When the water shut-off component 24 is disposed on the movable rear case 10 and fixed by the screws 26, the gel member 80 is compressed by the base member 82. At this point, the thickness of the gel member 80 at a portion close to an end surface of the movable rear case 20 becomes t₁, and the thickness of the gel member 80 at a portion contacting with the cable 13 becomes t₂. Assuming that the thickness of the cable 13 is t₃ and the thickness of the adhesive member 68 is t₄, a portion of the gel member 80 contacting with the cable 13 is more compressed than other portions for the amount of t₃+t₄, and adheres to the cable 13 under a compressing force caused by that amount. Since the gel member 80 is compressed under that compressing force, water may be appropriately shut off without allowing the creation of interstices around the cable 13.

The cable 13 inserted into the insertion hole 22 is bent in the insertion hole 22 and placed between the movable rear case 10 and a rear panel 110, for example. The rear panel 110 is disposed on a part or whole of the back surface of the movable rear case 10. The rear panel 110 covers the cable 13 inserted from the movable rear case 10 so that when the housing unit 4 slides to become an open state, for example, the cable 13 is not exposed exteriorly. The cable 13 extracted from the movable rear case 10 is placed along the rear panel 110, and at an end portion of the rear panel 110 the cable 13 reaches the housing unit 6 via a not-shown sliding module or the like.

The projecting portion 96 formed on the base member 82 passes through the thorough hole 98 of the gel member 80 and is placed in the insertion hole 22. In the insertion hole 22, the projecting portion 96 contacts with a bent portion of the cable 13. With this configuration, when some movement such as pulling the cable 13 occurs, the projecting portion 96 prevents the bent portion of the cable 13 from becoming loose in the insertion hole 22. The movement of the cable 13 includes the one caused by sliding the housing unit 4.

As depicted in FIG. 10, when the screws 26 are inserted into the screw portions 88 and 90, the cable 13 comes into contact with the concave portion 102 of the gel member 80. When the screws 26 are tightened into the projecting portions 106 and 108, the base member 82 is pressed to the movable rear case 10 and the gel member 80 is compressed. When the gel member 80 is compressed, the concave portions 100 and 102 of the gel member 80 are pressed onto the cable 13. Also, the compressed gel member 80 spreads at the periphery of the through holes 92 and 94 and the water shut-off component 24, for example, to fill interstices.

In the water shut-off component 24, the mounting distance between the screws 26 is set to W₃ (see FIG. 8), and the screws 26 is adapted to pass through the gel member 80 to mount the water shut-off component 24. At this point, the distance between the screw 26 and a side surface of the cable 13 is W₄, for example, and since the water shut-off component 24 may be fixed so that the distance between the screws 26 and the cable 13 becomes closer, it is possible to avoid detachment of the gel member 80 or generation of interstices at the periphery of the cable 13.

By allowing the screws 26 as fixing means to pass through the gel member 80, the size of the water shut-off component 24 in a lateral direction may be reduced, and a mounting space for the flexible circuit board 38 or the like may be saved in the housing unit 4. Meanwhile, on the movable front case 8, an area where the water shut-off component 24 interferes may be saved. Further, since the base member 82 is made of resin, the water shut-off component 24 is insulated from a mounted component 112 mounted on the movable front case 8.

According to such configuration, by allowing the fixing means, which fixes the holding member to the housing, to pass through the gel member, it is possible to fix the holding member to the housing at a position closer to a cable portion, and eliminate the difference of a compressing ratio of the gel member at different portions caused by whether a cable exist or not to more appropriately shut water off. By allowing the fixing means to pass through the gel member to fix the holding member at the periphery of the cable, a space for the water shut-off means may be saved. By forming the holding member in resin and placing the fixing means at the interior of the holding member, electrical influences on an antenna function or other mounted components of an electronic device may be avoided.

### Second Embodiment

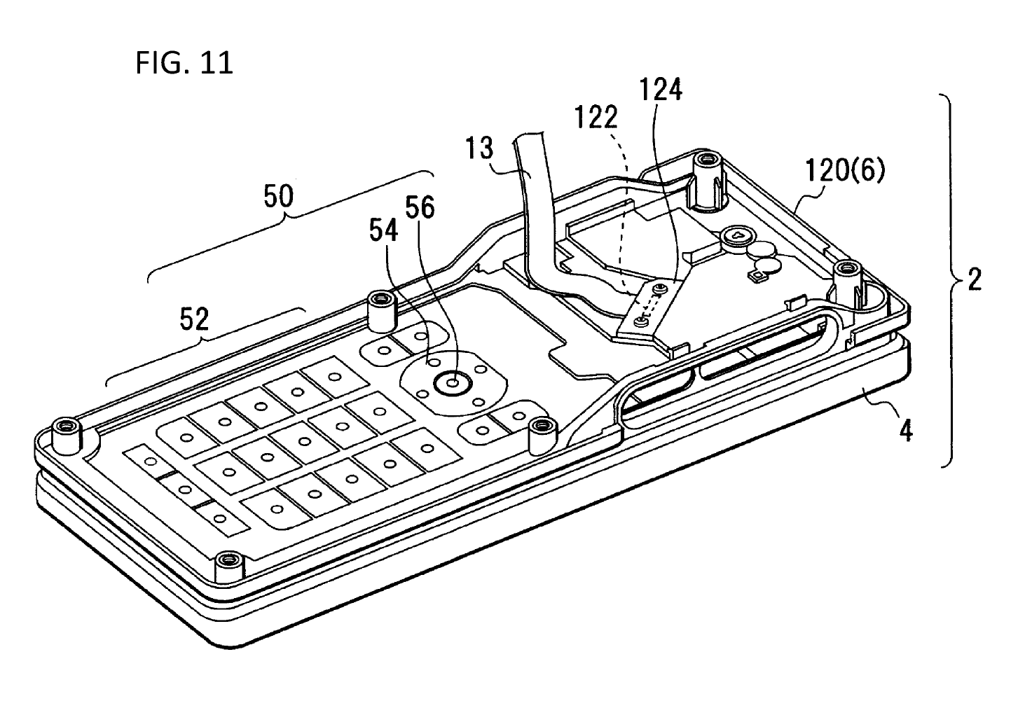

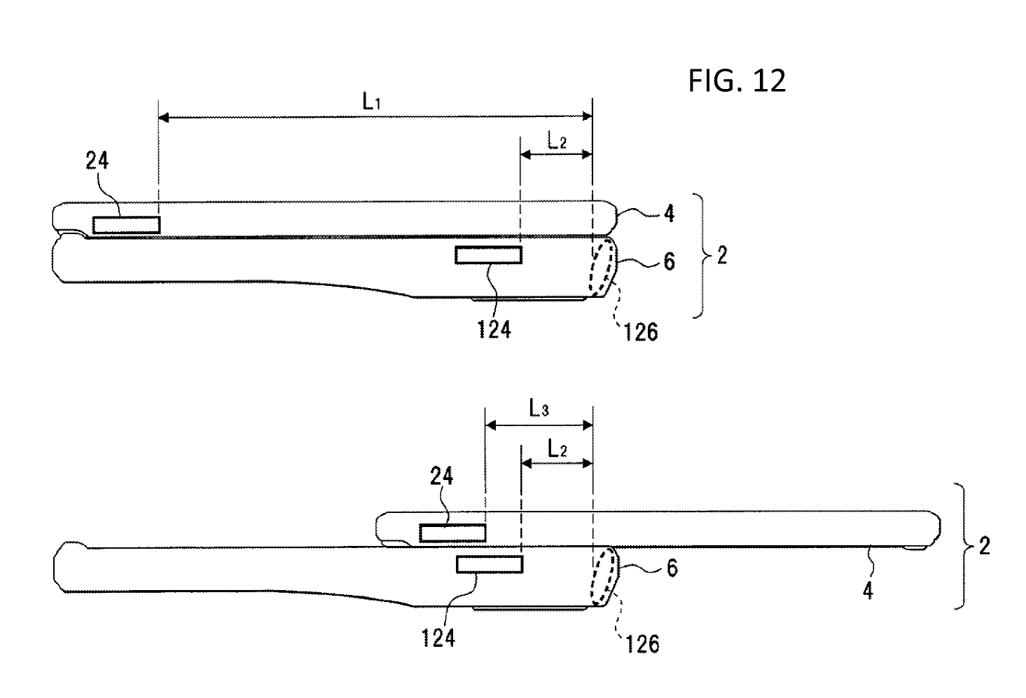

With reference to a second embodiment, FIGS. 11 and 12 will now be referenced. FIG. 11 is a diagram depicting an example of disposing a water shut-off component on a stationary housing unit of a second embodiment; and FIG. 12 is a diagram depicting an example of a state of the water shut-off component caused by opening and closing a cellular phone. Configurations depicted in FIGS. 11 and 12 are an example and the present embodiment is not limited to these.

The cellular phone 2 is an example of the present disclosure and represents a case where a water shut-off component 124 having a similar shape to the above-described water shut-off component 24 is disposed in the housing unit 6, for example. In the housing unit 4, the water shut-off component 24 is disposed at the insertion hole 22 of the movable rear case 10 as described in the above embodiment, and detailed description will thus be omitted.

The housing unit 6 is configured, for example, by stacking a stationary front case 120 and a not-shown stationary rear case on the housing unit 4 and installing a not-shown mounting board or the like at the interior thereof. Formed on the stationary front case 120 is an insertion hole 122 into which the cable 13 led from the housing unit 4 is inserted. The cable 13 inserted from the insertion hole 122 is connected to the mounting board, for example.

In the cellular phone 2, ingress of water or the like into the interior of the housing unit 6 needs to be prevented at the insertion hole 122 which opens for the outside of the housing unit 6, and the water shut-off component 124 is thus provided at the insertion hole 122. As described above, the water shut-off component 124 includes the gel member 80 and the base member 82 in a stacked manner, and fixed to the front case 120 by letting the screws 26 as fixing means pass through the gel member 80.

As depicted in FIG. 12, the water shut-off components 24 and 124 are disposed at the movable rear case 10 of the housing unit 4 and the stationary front case 120 of the housing unit 6, respectively. On the cellular phone 2, an antenna unit 126 is mounted at a front end of the housing unit 6 as a mounted component, for example.

As depicted in FIG. 12A, in a close state of the cellular phone 2, the water shut-off component 24 in the housing unit 4 and the antenna unit 126 are positioned at each of end portions of the cellular phone 2 in a longitudinal direction, and the distance therebetween is L₁, for example. And the distance between the water shut-off component 124 in the housing unit 6 and the antenna unit 126 is L₂, for example. On the other hand, as depicted in FIG. 12B, in an open state of the cellular phone 2, the water shut-off component 24 in the housing unit 4 comes closer to the water shut-off component 124 in the housing unit 6 such that a part thereof overlaps with the water shut-off component 24 in a vertical direction. At this point, the distance between the water shut-off component 24 and the antenna unit 126 is L₃, for example.

In such configuration, since metallic components such as the screws for fixing the water shut-off components are insulated with resin material, as described above, electrical or magnetic influences on mounted components in the housing unit 6 may be avoided even when the water shut-off component comes closer to the mounted components by an opening or closing operation. Conventionally, the gel member in a water shut-off structure is fixed by a sheet metal and that causes influences on the antenna unit 126, such as deteriorating antenna characteristics, when the water shut-off component comes closer to the antenna unit 126. On the other hand, by using a base member made of resin, as with the case of the water shut-off components 24 and 124, influences on antenna characteristics may be avoided even when an opening or closing operation is performed on the housing units 4 and 6.

### Third Embodiment

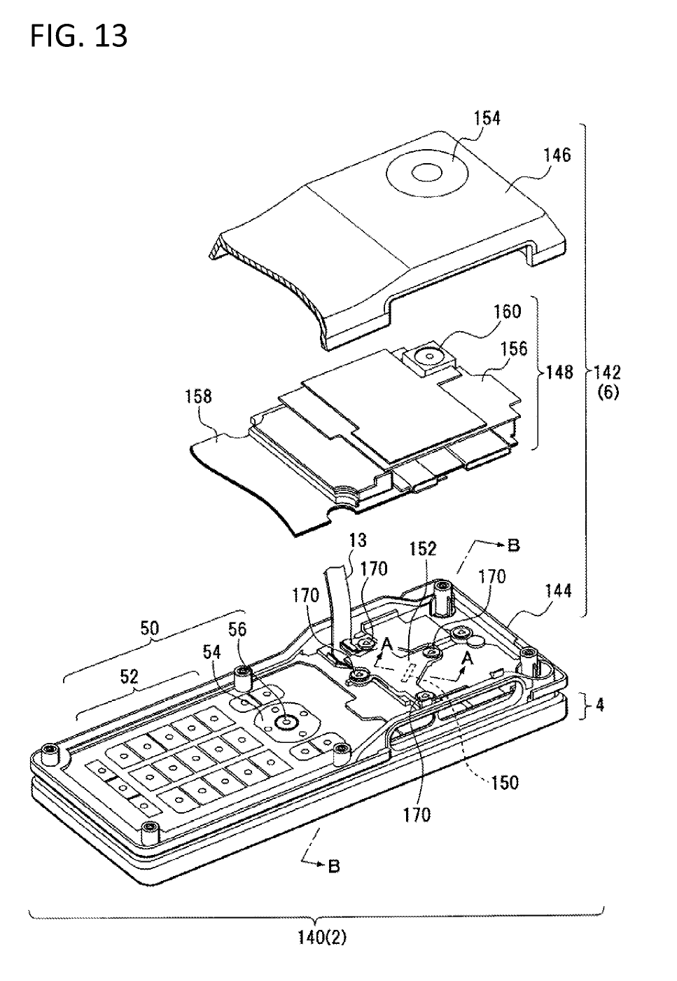

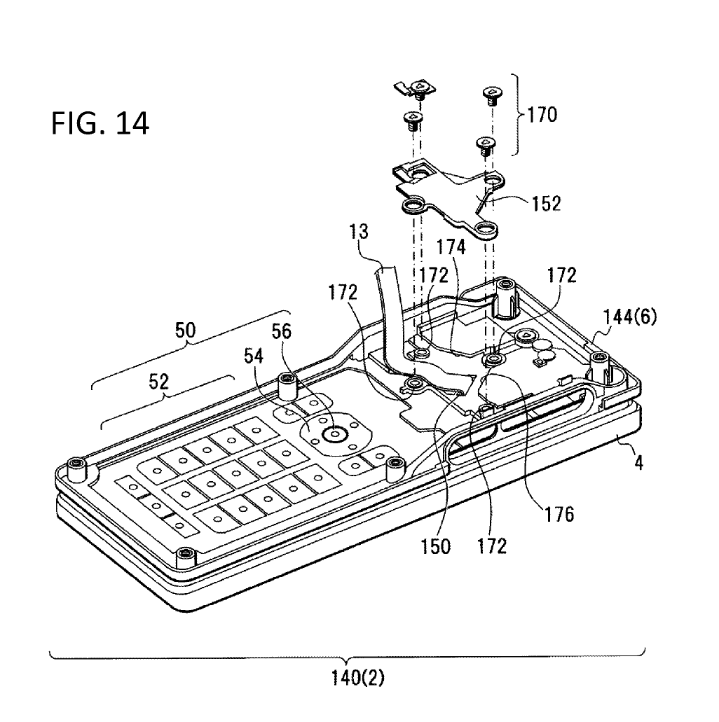

With respect to a third embodiment, FIGS. 13 and 14 will now be referenced. FIG. 13 is a diagram depicting an example of the water shut-off structure in a stationary housing unit of a third embodiment; and FIG. 14 is a diagram depicting a configuration example of the water shut-off component in the stationary housing unit. Configurations depicted in FIGS. 13 and 14 are an example and the present embodiment is not limited to these.

A cellular phone 140 is an example of an electronic device of the present disclosure in which the first housing unit 4 and a second housing unit 142 are slidably connected. The housing unit 4 is an example of a movable housing unit and connected to the housing unit 142 by the cable 13. As described above, the movable rear case 10 of the housing unit 4 includes the water shut-off component 24 (see FIG. 1). On the other hand, the housing unit 142 includes a water shut-off structure, which is different from the one in the housing unit 4, at an insertion hole for the cable 13.

The housing unit 142, an example of a second housing unit, includes a stationary front case 144, which is adjacent to the housing unit 4, and a stationary rear case 146 and provides a circuit board unit 148 at the interior thereof, for example. On the stationary front case 144, an insertion hole 150 is formed through which the cable 13 from the housing unit 4 is inserted into the interior of the housing unit 142. With respect to the insertion hole 150, a water shut-off component 152 is provided on the inner side of the stationary front case 144.

The stationary rear case 146 constitutes a back cover of the cellular phone 140, for example, on which a window portion 154 for a camera function and the like are provided.

The circuit board unit 148, which is a component unitizing circuit boards of functional components in the housing unit 6 and the like, includes a control board 156 for a CPU, a memory, and the like and a circuit board 158 on which sensors, light emitting means, and the like are mounted for ten keys 52, an enter key 56, a cursor key 54, and the like. The circuit board unit 148 also includes the above-described antenna function, a camera 160, and the like.

As depicted in FIG. 14, formed on the stationary front case 144 are: screw holes 172 into which a plurality of screws 170 are inserted to fix the water shut-off component 152 at the periphery of the insertion hole 150; guide walls 174 and 176 for guiding side surfaces of the water shut-off component 152; and the like. The screw holes 172 are formed at a circumferential edge of the water shut-off component 152, and arranged so that the screws 170 may be tightened securely to the water shut-off component 152 without creating interstices between the water shut-off component 152 and the insertion hole 150, for example. In the water shut-off component 152 depicted in FIG. 14, four screws 170 are diagonally arranged, for example. The guide walls 174 and 176 are an example of holding means for holding the water shut-off component 152 at a predetermined mounting position by guiding a part or whole of side surface portions of the water shut-off component 152. The guide walls 174 and 176 may be integrally molded with the stationary front case 144, or created by mounting separate parts.

The number or shape of the screws 170 and the guide walls 172 and 174 for fixing the water shut-off component 152 may be determined in accordance with the shape or size of the movable front case 144 or with respect to mounted components or the like in the housing unit 142, for example.

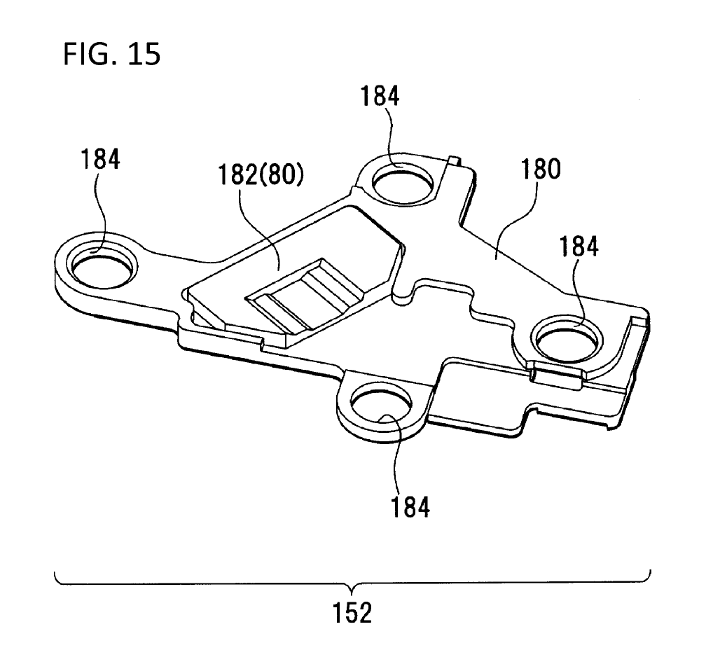

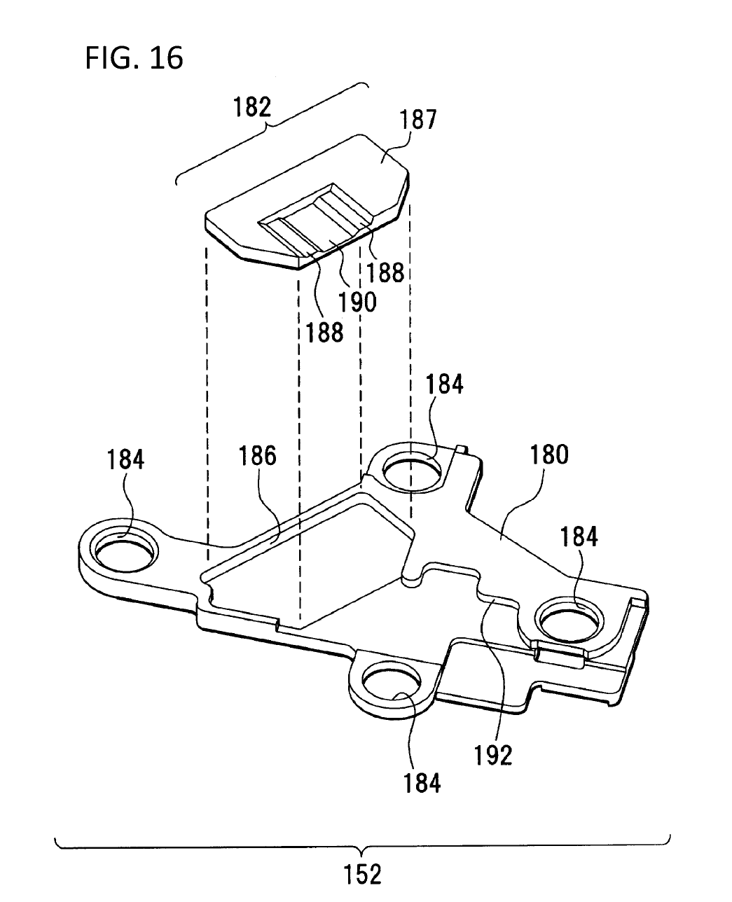

With respect to a configuration of the water shut-off component, FIGS. 15 and 16 will now be referenced. FIG. 15 is a diagram depicting a configuration example of the water shut-off component at a side thereof which contacts with a cable; and FIG. 16 is a diagram depicting a configuration example of the water shut-off component. Configurations depicted in FIGS. 15 and 16 are an example and the present embodiment is not limited to these.

The water shut-off component 152 includes, for example, a base member 180 and a gel member 182 for covering the cable 13 and the insertion hole 150. The gel member 182 is held by the base member 180, and deforms by being compressed to the side of the stationary front case 144, for example, to fill interstices between the insertion hole 150 and the cable 13.

The base member 180, or holding means for holding the gel member 182, is an example of another holding means of the present disclosure and formed in synthetic resin such as polycarbonate containing glass fibers, for example. On a circumferential edge of the base member 180, a plurality of through holes 184 are formed at positions corresponding to the screw holes 172 of the stationary front case 144. The through holes 184 are means for fixing the base member 180 to the stationary front case 144 by anchoring a part of the screws 170 passing therethrough. The through holes 184 are also means for applying a pressure to the gel member 182 by a fixing pressure generated by the anchored screws 170. By the pressure received from the base member 180, the gel member 182 is pressed to the insertion hole 150 of the stationary front case 144 and the cable 13.

On the gel member 182 depicted in FIG. 16, a flat surface portion 187 and steps aligned with the position of the cable 13 are formed, for example. The steps include a first concave portion 188 and a second concave portion 190 in the descending order of the thickness of the gel member 182. The flat surface portion 187 contacts with the periphery of the insertion hole 150 of the stationary front case 144. The concave portions 188 and 190 are configured similarly to the concave portions 100 and 102 formed on the above-described gel member 80. For example, the concave portion 188 is formed at both sides of the concave portion 190 in a longitudinal direction of the gel member 182. The concave portion 188 contacts with the cable 13 and covers the periphery thereof, for example. The concave portion 190 is formed so that the width thereof is smaller than the width of the cable 13, for example, and positioned at a central portion on a surface of the cable 13.

The depth of the concave portions 188 and 190 may be determined in consideration of the thickness of the cable 13 or the like, for example.

On the base member 180, a first guide portion 186 is formed at a mounting position of the gel member 182, and a second guide portion 192 is formed at a position adjacent to the gel member 182. The guide portion 186 is formed by engraving a portion of the base member 180 according the shape of the gel member 182, for example, and constitutes a concave portion to surround the gel member 182 to house and hold it. The guide portion 186 is formed so that the height thereof is equal to the thickness of the gel member 182, or a part of an upper portion of the gel member 182 projects from the base member 180, for example.

The guide portion 192 is an example of means for guiding the cable 13, inserted from the insertion hole 150 to the interior of the housing unit 142, in a predetermined direction to a connecter or the like of the circuit board unit 148 or the like, and is formed in conjunction with the guide portion 186, for example. The guide portion 192 is formed by engraving a part of the base member 180, for example. The guide portion 192 is engraved according to the thickness of the cable 13, for example, to hold and lead the cable 13.

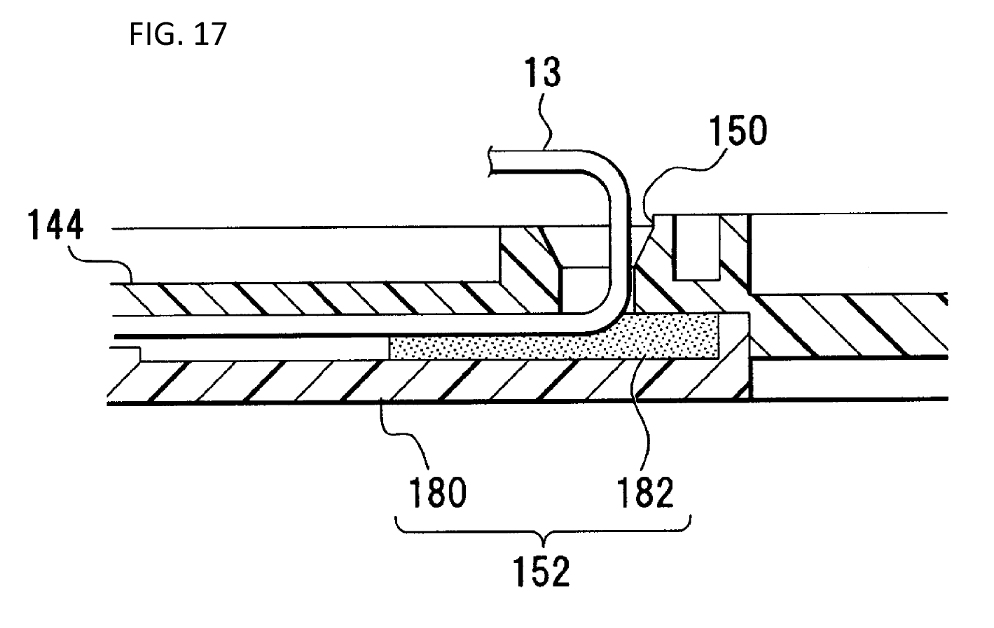

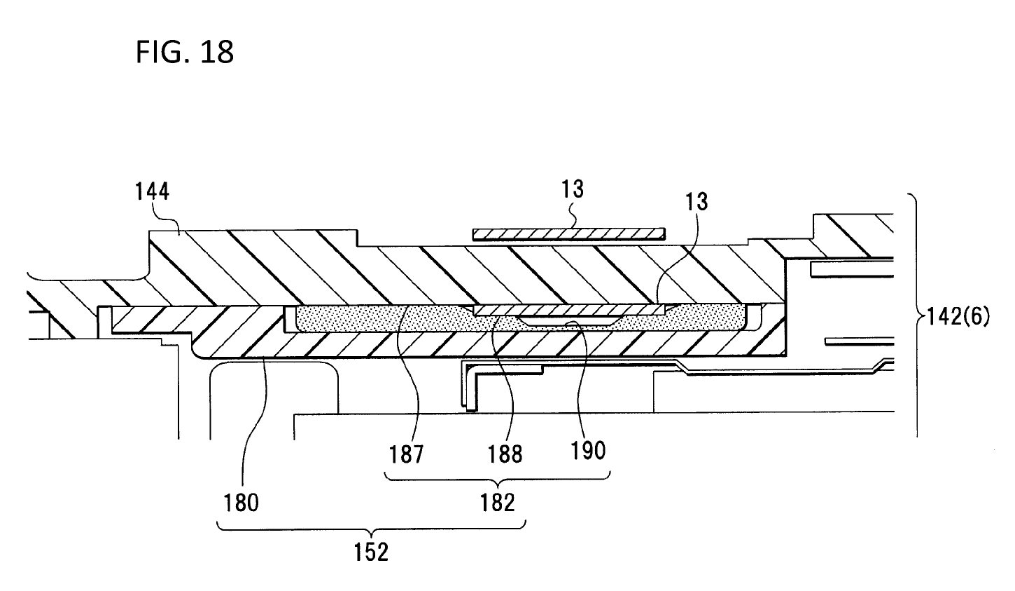

With respect to a water shut-off state of the stationary front case, FIGS. 17 and 18 will now be referenced. FIG. 17 is an example of a cross-sectional view taking along line A-A of FIG. 13; and FIG. 18 is an example of a cross-sectional view taking along line B-B of FIG. 13. Configurations depicted in FIGS. 17 and 18 are an example and the present embodiment is not limited to these.

As depicted in FIG. 17, when the screws 170 are tightened to the stationary front case 144 via the through holes 184 of the base member 180, the base member 180 and the gel member 182 are pressed to the stationary front case 144. This enables the gel member 182 to cover the insertion hole 150 into which the cable 13 is inserted from the housing unit 4 (not shown) and fill interstices at the periphery of the cable 13 or the like.

As depicted in FIG. 18, when the water shut-off component 152 is mounted on the insertion hole 150, the cable 13 contacts with the concave portion 188 of the gel member 182. By tightening the screws 170, the base member 180 is pressed to the stationary front case 144, and the gel member 182 is compressed such that the concave portions 188 and 190 adhere to the cable 13.

In the water shut-off component 152, the screws 170 are arranged to avoid the area of the gel member 182. This enables to mount the water shut-off component 152 on the insertion hole 150 without interfering with, for example, the circuit board unit 148 provided at the periphery thereof in a height direction.

According to such configuration, different water shut-off components may be used in a first housing unit and a second housing unit in accordance with functional components or circuit boards mounted therein to reliably shut water off. Also, by forming a holding member in resin, electrical influences on an antenna function or other mounted components in an electronic device may be avoided.

Features and benefits of the first to third embodiments will now be listed.

(1) Since a water shut-off component for a flexible cable in an electronic device of the present disclosure shuts water off by pressing a gel member with a case component made of resin, interferences or the like to an antenna do not occur even when the water shut-off component comes closer to the antenna by sliding a housing, enabling to avoid deterioration of antenna characteristics.

(2) In this water shut-off component, by integrating the gel member and a base member and tightening screws into bosses through the gel member to fix to a case, a water shut-off structure may be downsized.

(3) By providing a projecting portion on a part of the water shut-off component to put into an insertion hole of the housing, it is possible to hold a flexible cable so as not become loose along a wiring route thereof except a portion of the insertion hole.

### Another Embodiment

(1) Even though the above embodiments describe a case in which the water shut-off component 24 fixed through the gel member is provided in the movable housing unit 4, the present invention is not limited to this. For example, the water shut-off component 152 fixed at the outside of the gel member may be mounted on the movable rear case 10 of the movable housing unit 4. In this case, the water shut-off component 24 fixed through the gel member may be provided in the stationary housing unit 6.

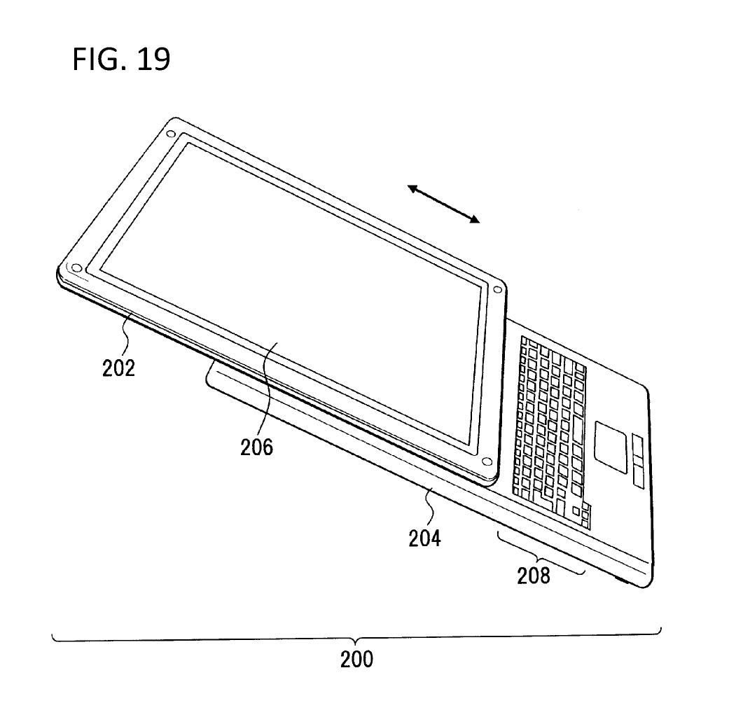

(2) Even though the above embodiments describe a configuration of a cellular phone as an example of an electronic device, the present invention is not limited to this. For example, as depicted in FIG. 19, a PC (personal computer) 200 having mutually slidable first and second housing units 202 and 204 may be used as an example. The housing unit 202 includes, for example, a display unit 206. The housing unit 204 includes, for example, an input operation unit 208 such as a keyboard. The housing units 202 and 204 of the PC 200 are connected by a not-shown cable, for example. A housing case for each of the housing units 202 and 204 has an insertion hole through which the cable passes, and a water shut-off component such as the one described above is provided at the insertion hole.

Other examples of an electronic device of the present invention include a portable game machine and a personal digital assistant (PDA) in which a plurality of housing units are slidably connected.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a depicting of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic device comprising:
a housing that has a cable insertion hole;
a gel member that covers the cable insertion hole to shut water off, a cable being inserted through the cable insertion hole;
a holding member, formed in synthetic resin, that has a first protruding portion to pass through the gel member, the first protruding portion projecting into the cable insertion hole, the holding member mounting and holding the gel member to the housing; and
a fixing unit that fixes the holding member to the housing by passing through the gel member.

2. The electronic device of claims 1, wherein
the first protruding portion of the holding member contacts with the gel member and a through hole or a screw hole, through which the fixing unit passes, are provided at the first protruding portion.

3. The electronic device of claim 1, wherein
the holding member has a opposite protruding portion that protrudes from a first surface of the holding member opposite to a second surface of the holding member, the second surface contacting with the gel member, the opposite protruding portion housing a head potion of the fixing unit inserted into the through hole or the screw hole.

4. The electronic device of claim 1, wherein
the gel member includes:
a first through hole through which the fixing unit passes; and
a second through hole through which the first protruding portion passes.

5. The electronic device of claim 1, wherein
the holding member includes a second protruding portion that passes through the gel member to project into the cable insertion hole.

6. The electronic device of claim 1, wherein
the housing includes:
a first housing into which one end of the cable is inserted; and
a second housing connected with the first housing by the cable into which the other end of the cable is inserted,
wherein the first housing includes a water shut-off structure in which the holding member is fixed by the fixing unit passing through the gel member.

7. The electronic device of claim 6, wherein
the second housing includes:
an other holding member, formed in synthetic resin, to hold the gel member while having a through hole through which a fixing member passes at the periphery of the gel member; and
an other fixing unit to fix the other holding member to the second housing.

8. The electronic device of claim 7, wherein
the other holding member has a housing concave portion to house and hold the gel member.
